(19) United States
(12) Patent Application Publication
(10) Pub. No.: US 2025/0132205 A1
(43) Pub. Date: Apr. 24, 2025

(54) SEMICONDUCTOR WAFER THINNED BY CRACK PROPAGATION

(71) Applicant: Western Digital Technologies, Inc., San Jose, CA (US)

(72) Inventors: Fan Ye, Shanghai (CN); Xinnan Wang, Shanghai (CN); Huo Liang Chen, Shanghai (CN); Shuqian Zhang, Shanghai (CN); Weiting Jiang, Shanghai (CN)

(73) Assignee: Western Digital Technologies, Inc., San Jose, CA (US)

(21) Appl. No.: 18/493,527

(22) Filed: Oct. 24, 2023

(51) Int. Cl. H01L 21/78; H01L 21/268; H01L 21/304

(52) U.S. Cl. CPC H01L 21/7806; H01L 21/268; H01L 21/3043

(57) ABSTRACT

A semiconductor wafer is prepared with the silicon {111} crystalline plane parallel to the major surfaces of the wafer. After preparation of the wafer with the desired {111} crystalline plane orientation, integrated circuit semiconductor dies may be defined in one of the major surfaces of the wafer. Stress defects may then be formed in the wafer in a {111} crystalline plane at a depth corresponding to the final thickness of the wafer. Cracks propagate from the stress defects in the plane of the stress defects, effectively cleaving the wafer in two at the desired finished thickness of the wafer.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, cellular telephones and solid-state drives.

Wafers currently are shipped from the wafer fab with a typical thickness of 760 microns to prevent damage during transport, and then thinned once the individual semiconductor dies are defined within the wafer. In order to maximize storage capacity for a given form factor storage device, storage device semiconductor dies, and the wafers from which they are made, are being fabricated to ever-decreasing thicknesses. Currently, wafers are being thinned for example to 36 microns, 25 microns and thinner.

A popular method of thinning semiconductor wafers involves a backgrinding process where the back, inactive surface of the wafer is thinned while the front surface of the wafer including the integrated circuits is covered by protective tape and supported on a chuck. Conventional backgrinding processes typically involve a coarse grinding step using a wheel with large particles. This process thins the wafer close to its final thickness, but results in deep surface scratches. Cracks in the wafer, such as windmill cracks, can also form during the coarse grinding step. A fine grinding step is then performed using a wheel with smaller particles to remove the damaged layer. This step removes some, but not all, of the scratches, and can create fine scratches of its own. A third step is then performed with a polishing wheel. Again, this removes some, but not all, of the surface scratches.

The multiple separate steps involved in a conventional backgrind process result in a long production time. Moreover, as noted, the final wafer may contain scratches and cracks. These scratches and cracks can cause damage to the wafer during the semiconductor die fabrication processes, or otherwise impair the operation of semiconductor dies formed in the wafer.

### DESCRIPTION OF THE DRAWINGS

FIG. 1 is a flowchart for forming a semiconductor wafer and semiconductor dies according to embodiments of the present technology.

FIG. 2 is a schematic ball and stick model of silicon illustrating the {111} crystalline plane.

FIG. 3 is a front view of a semiconductor wafer showing a first major surface of the wafer.

FIG. 4 is an enlarged cross-sectional edge view showing the circuit layer within a semiconductor die.

FIG. 5 is a perspective view of a first stealth lasing process for generating stress defects in a {111} crystalline plane within an interior of the semiconductor wafer according to embodiments of the present technology.

FIG. 6 is a perspective view of a second stealth lasing process for generating stress defects in a {111} crystalline plane within an interior of the semiconductor wafer according to embodiments of the present technology.

FIG. 7 is a perspective view of an edge lasing process for generating stress defects in a {111} crystalline plane around the circumference of the semiconductor wafer according to embodiments of the present technology.

FIG. 8 is a perspective view of an edge cutting process for generating stress defects in a {111} crystalline plane around the circumference of the semiconductor wafer according to embodiments of the present technology.

FIG. 9 is an edge view of a semiconductor wafer and a vacuum tip against the inactive surface of the semiconductor wafer according to embodiments of the present technology.

FIG. 10 is an edge view of a semiconductor wafer and a vacuum tip against the inactive surface of the semiconductor wafer according to embodiments of the present technology.

FIG. 11 is a perspective view of a die cut from a wafer thinned by the crack propagation method according to embodiments of the present technology.

### DETAILED DESCRIPTION

The present technology will now be described with reference to the figures, which in general, relate to thinning of a semiconductor wafer prepared with the silicon {111} crystalline plane parallel to the major surfaces of the wafer. After preparation of the wafer with the desired {111} crystalline plane orientation, integrated circuit semiconductor dies may be defined in one of the major surfaces of the wafer, referred to herein as the active surface of the wafer. Thereafter, with active surface of the wafer supported on a vacuum chuck, stress defects may be formed in the wafer in a {111} crystalline plane at a depth corresponding to the final thickness of the wafer. These stress defects may be formed by a variety of methods, including stealth lasing within an interior of the wafer, and stress defects formed around a circumference of the wafer by a laser or saw blade.

Given low surface energy of silicon in the {111} crystalline plane, cracks propagate from the stress defects in the plane of the stress defects, effectively cleaving the wafer in two at the desired finished thickness of the wafer. The cleaved portion of the wafer may be gripped with a vacuum tip, removed and discarded. What remains is the semiconductor wafer, thinned to the final desired thickness, with a highly planar back surface devoid of cracks or scratches. The wafer may thereafter be diced into individual semiconductor dies, as by stealth lasing or saw blade cutting in planes perpendicular to the {111} crystalline plane of the wafer.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

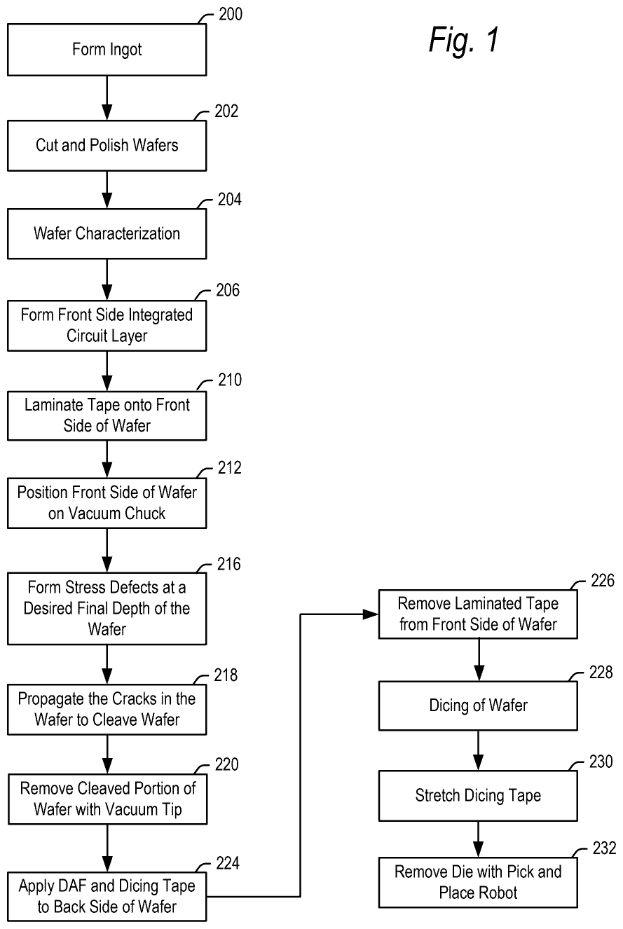

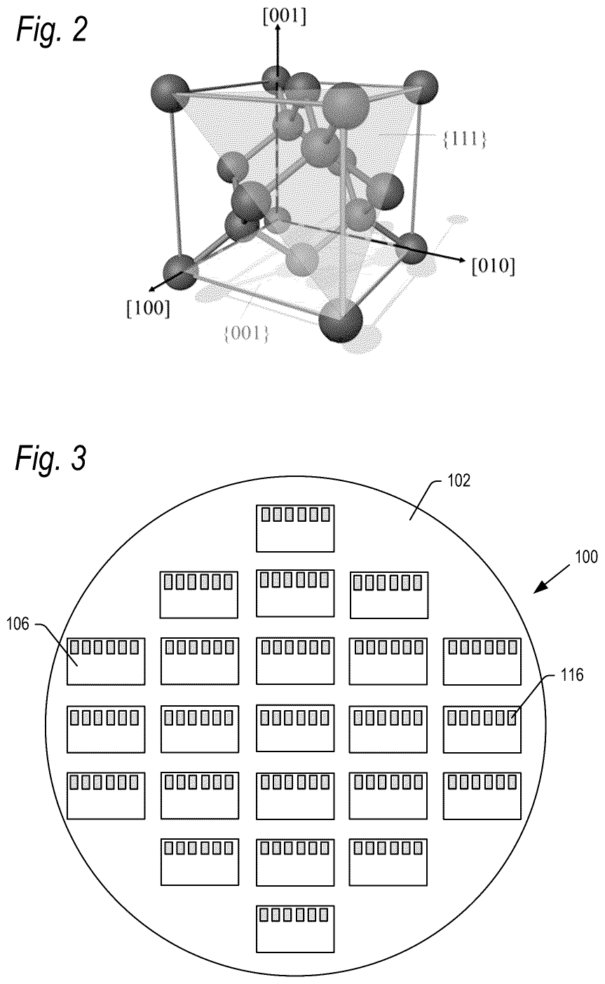

An embodiment of the present technology will now be explained with reference to the flowchart of FIG. 1, and the views of FIGS. 2-11. Referring initially to the flowchart of FIG. 1, an ingot of silicon wafer material may be formed in step 200. In accordance with aspects of the present technology, the ingot is formed with a {111} crystalline plane orientation. FIG. 2 is a schematic ball and stick model of molecular silicon. The {111} crystalline plane (shaded in FIG. 2) is the plane perpendicular to a vector having x, y and z coordinates of [1,1,1]. As explained below, the ingot is formed so that wafers cut from the ingot have the {111} crystalline plane parallel to the front and back major surfaces of the wafers.

Step 200 begins by melting high-purity polysilicon feedstock in a crucible positioned within a heat source such as a furnace. Once the polysilicon is melted, a small seed crystal of silicon is carefully positioned with a {111} crystalline orientation relative to the crucible and lowered into the molten silicon. The seed crystal serves as a template for the growth of a single-crystal silicon ingot, and determines the orientation of the entire ingot. Once the seed crystal is positioned in the molten silicon, the silicon is caused to crystallize onto the seed crystal by a temperature gradient within the crucible. The temperature gradient may be created by the Czochralski method, where the crucible is slowly pulled upward out of the furnace. As the crucible rises, the molten silicon adheres to the seed crystal and solidifies in a single-crystal form. The temperature gradient may alternatively be created by the Float Zone method, where the seed crystal is slowly rotated in the molten silicon. Silicon solidifies onto seed crystal as it rotates, forming a single-crystal ingot.

As the crystal grows, the temperature is controlled to maintain a stable growth rate and prevent defects. The temperature is gradually reduced as the crystal elongates. In embodiments, dopant materials may be added to the molten silicon to introduce controlled impurities into the silicon ingot to create specific electrical properties in the integrated circuit semiconductor dies to be formed in the wafers. In embodiments, after the ingot has reached the desired length and thickness, it may also undergo an annealing process to relieve internal stresses and remove defects, further ensuring a high-quality crystal in the ingot.

Once completed, the silicon ingot is removed from the furnace and cooled. In step 202, the ingot is sliced into thin wafers using for example a precision diamond saw. Each wafer is cut so that the major surfaces of the wafer lie in the {111} plane of the single-crystal silicon ingot. In embodiments, the wafers may be cut to a thickness of 760 μm, which is a sturdy thickness preventing damage to the wafers when they are shipped for further processing into semiconductor dies. Step 202 may also include mechanical or chemical-mechanical polishing (CMP) of the major surfaces of each wafer to ensure smooth surfaces. A wafer characterization step 204 may also be performed where the wafers are checked to verify their {111} crystalline orientation and quality, using techniques such as X-ray diffraction and electron microscopy.

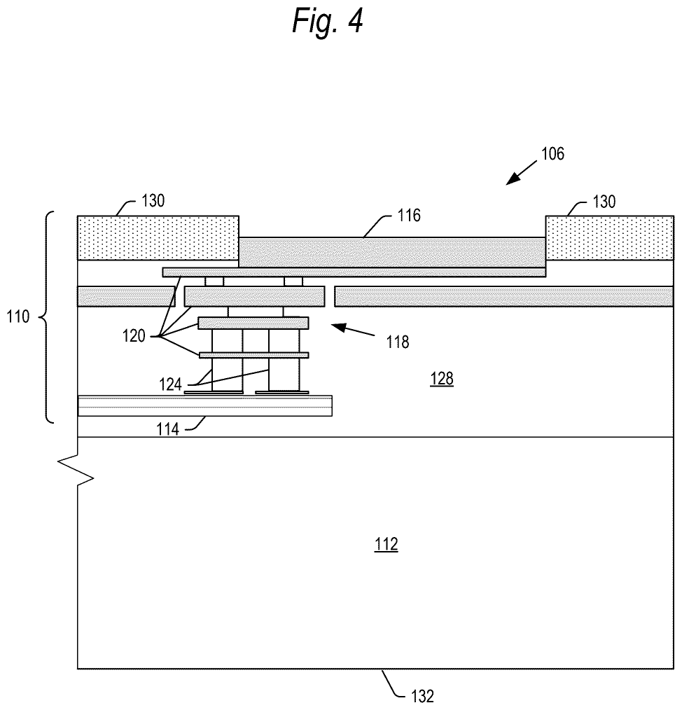

In step 206, the front or first major surface may undergo various processing steps to divide the wafer into respective integrated circuit semiconductor dies. FIG. 3 is a top view of a wafer 100 having a front surface 102 within which a number of integrated circuit semiconductor dies 106 are formed (one of which is numbered in FIG. 3). FIG. 4 is a cross-sectional side view of an exemplary semiconductor die 106 of the wafer 100 showing the integrated circuit layer 110 formed in a silicon substrate 112. Integrated circuit layer 110 may in general include integrated circuits 114 electrically coupled to surface die bond pads 116 by metallization layers 118. The integrated circuits 114 may be formed by various processes including for example deposition, patterning and doping of metals, metal oxides and silicon.

After formation of the integrated circuits 114, metallization layers 118 may be defined including metal interconnects 120 and vias 124 layered sequentially in a dielectric film 128. As is known in the art, the metal interconnects 120, vias 124 and dielectric film 128 may be formed for example by damascene processes a layer at a time using photolithography and thin-film deposition. The metal interconnects 120 and vias 124 may be used to form conductive nodes for transferring signals and voltages between the die bond pads 116 and integrated circuits 114. A passivation layer 130 may be formed on top of the upper dielectric film layer 128. The passivation layer 130 may be etched to expose the die bond pads 116.

In embodiments, the semiconductor dies 106 may for example be flash memory dies such as 2D NAND flash memory or 3D BiCS (Bit Cost Scaling), V-NAND or other 3D flash memory, but other types of dies 106 may be used. These other types of semiconductor dies include but are not limited to RAM, a controller, an SOC (system on a chip), a processor or other types of semiconductor dies.

It is known to create a single integrated memory die module comprised of a first semiconductor die including the memory array, and a second semiconductor die including the logic circuit such as CMOS integrated circuits. An example of such an integrated memory die module is disclosed in Published U.S. Patent Application No. U.S. 2019/0341375, entitled “Bifurcated Memory Die Module Semiconductor Device.” Dies 106 may further be from a wafer of such bifurcated memory array semiconductor dies, or from a wafer of such bifurcated CMOS logic circuit dies.

The number of dies 106 shown on wafer 100 in FIG. 3 is for illustrative purposes, and wafer 100 may include more semiconductor dies 106 than is shown in further embodiments. Similarly, the number of bond pads 116 on each semiconductor die 106 is shown for illustrative purposes, and each die 106 may include more die bond pads than is shown in further embodiments. In accordance with aspects of the present technology, the wafer 100 may be thinned by cleaving the silicon substrate layer 112 as explained below, leaving the semiconductor dies 106 intact in the front surface 102 of the wafer 100.

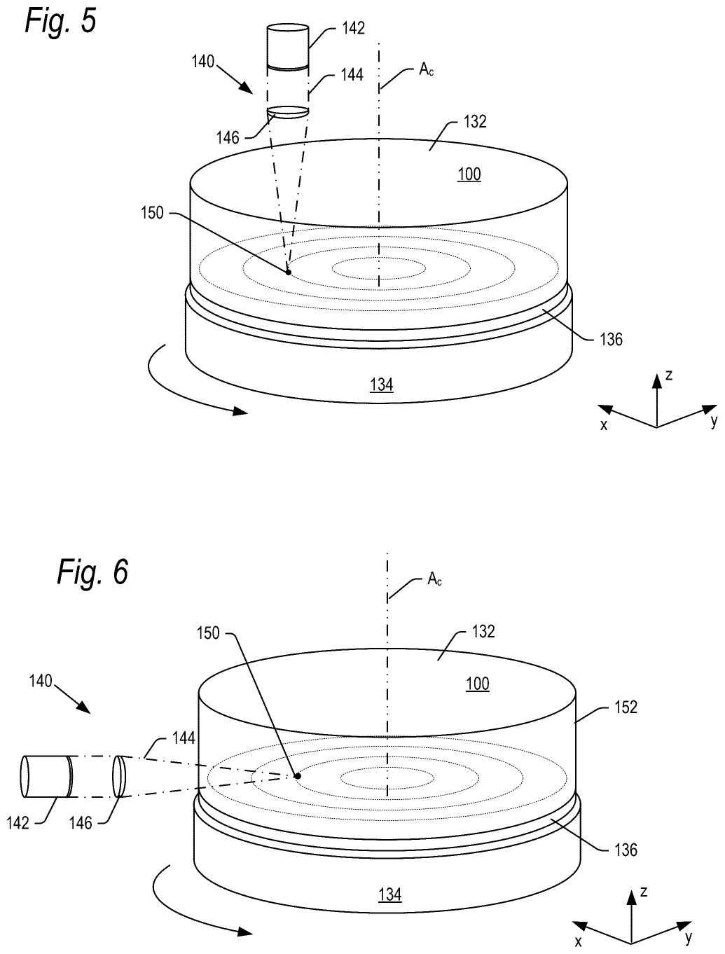

After formation of the integrated circuit layer 110 in step 206, a layer of tape may be laminated onto the active, major surface 102 in step 210. The wafer 100 may then be turned over so that the active surface 102 is supported on a vacuum chuck in step 212 with an inactive surface 132 (FIG. 4) of wafer 100 facing upward. The wafer 100 may then be thinned to its final thickness in accordance with the present technology as will now be explained with reference to steps 216-220 and FIGS. 5-10.

The present technology recognizes and makes use of the low surface energy of silicon in the {111} crystalline plane to readily propagate cracks in the {111} crystalline plane upon introduction of stress defects in that plane. In particular, as compared to other crystalline planes, it has been determined that the {111} crystalline plane of silicon has the lowest surface energy, thus making this plane most optimal for crack propagation. As described above, the wafer 100 is fabricated so that the {111} crystalline plane is parallel to the major surfaces 102 and 132. Thus, upon introduction of stress defects in a plane parallel to the major surfaces (step 216), the crystal orientation in wafer 100 results in crack propagation in that plane (step 218) to cleave the wafer in two at the desired final thickness as explained below.

Referring initially to FIG. 5, in one embodiment, a number of stress defects may be introduced in an internal {111} crystalline plane parallel to the surfaces 102 and 132 using a horizontal stealth lasing technique, which will now be described. The wafer 100 may be supported on a chuck 134 or other support surface with the layer of tape 136 separating the active surface 102 from the chuck 134. The second major surface 132 faces upward. In embodiments, the chuck 134 is configured to rotate about a central axis Ac. The wafer 100 is centered on the chuck 134 so that the wafer is also concentric about the central axis Ac.

A laser assembly 140 is positioned above the wafer 100 to emit a pulsed laser beam though the inactive surface 132 into the depth of the wafer 100, specifically into the silicon substrate region 112. The laser assembly 140 may include a laser generator 142 for generating a laser beam 144, and optics 146 for focusing the laser beam 144 to a point within the interior of the wafer 100 as explained below. The laser generator may generate an infrared or near-infrared laser, at a wavelength of for example 1342 nm. Other wavelength lasers are contemplated. The peak power of laser generator 142 and beam area together define the peak power density of laser beam 144:

peak power density W/m2=peak power (W)/beam area(m2).

In one example, the peak power of laser generator 142 may be 2 W, and the beam diameter may be ≈2-4 μm. These values are by way of example only, and may vary in further embodiments. In one example, the laser generator may pulse the laser beam 144 at 90 KHz.

The optics 146 may for example include one or more collimating lenses capable of focusing the parallel wavelengths of light from laser generator 142 to a focal point. The laser assembly 140 is shown schematically, and may include additional components for generating and focusing the laser, including a contoller for controlling the intensity and pulse frequency of the laser. When the laser beam 144 hits the second major surface 132, the beam refracts due to light in the laser beam slowing as it passes into the silicon substrate 112. The amount of refraction may vary depending on the refractive index of the substrate 112 material. As shown in FIG. 5, the collimating lens 146 causes the beam 144 to converge to a focal point where the energy of the laser beam 144 is most concentrated. This concentrated energy creates a stress defect 150 at the focal point of the laser beam 144.

In accordance with the present technology, the laser assembly 140 is positioned along the vertical z-axis and configured to emit the beam 144 into the silicon substrate region 112 to focus at points in a plane within the wafer 100 equating to the final thickness of the wafer 100. In embodiments, this final thickness may be between 20 μm to 100 μm, including for example 25 μm and 36 μm, but it is understood that the laser assembly 140 may be positioned to achieve other final thicknesses of wafer 100 within this range or outside of this range.

In order to create multiple stress defects 150 in the desired plane, the chuck 134 may rotate, and the laser assembly 140 may translate between inner and outer radii of wafer 100. The laser assembly 140 may be positioned at a first radius for example adjacent the central axis of rotation Ac of the wafer 100, and the wafer 100 may then be rotated on chuck 134 through a full cycle) (360° while laser emits pulses of light at the predefined frequency. After completion of the first cycle, the position of the laser assembly may then be adjusted to a new radius, and the wafer is again rotated through a full cycle while the laser emits pulses of light at the predefined frequency. This process may continue in multiple cycles through increasing radii until the laser is focused at or near the outer circumference of the wafer 100. It is understood that the stress defects 150 may be generated at multiple points through other coordinated movements of the wafer chuck 134 and laser assembly 140 in further embodiments. In one such further embodiment, the laser generator 142 may remain stationary, and the laser beam 144 may be moved between the inner and outer radii of the wafer 100 using optics such as collimating lens 146.

In one example, a stress defect 150 may be created around a given radius once every 5 μm to 100 μm, though the stress defects 150 may be spaced closer to each other or farther from each other than that range in further embodiments. FIG. 5 shows a simplified example including three different radii at which the laser is positioned for illustrative purposes and there be more radii at which the laser cycles are performed. For example, for a 300 mm wafer, there may be between 5 and 250 different cycles, each performed at equally spaced radii. There may be more or less cycles in further embodiments.

FIG. 5 shows one example of a horizontal stealth lasing process for generating stress defects in a horizontal plane parallel to the major surfaces 102, 132. FIG. 6 shows a further example of horizontal stealth lasing for generating stress defects in a horizontal plane parallel to the major surfaces 102, 132. This embodiment may generate stress defects 150 at multiple radii, and at multiple positions at each radii. However, in this embodiment, the laser assembly 140 may be positioned at an axis perpendicular to the central axis of rotation Ac of the wafer 100 to emit the laser through a circumferential edge 152 of the wafer 100. The radii at which the laser beam 144 focuses may be changed for example by moving the collimating lens 146 toward/away from the wafer 100. All other features and parameters may be as described above with respect to FIG. 5.

In the embodiments described above with respect to FIGS. 5 and 6, the laser is pulsed to create discrete points of stress defects 150. As explained below, cracks will propagate between the stress defects 150 to effectively cleave the wafer 100 in two. In further embodiments, the laser of FIGS. 5 and 6 may emit a continuous beam, so that instead of discrete points of stress defects 150, there are continuous lines of stress defects 150. Moreover, instead of rotating the wafer and creating stress defects (discrete or in a continuous line) in a curved pattern at different radii, the chuck 134 may be held stationary, and the laser assembly 140 may be translated in the x-y plane to create discrete or continuous line stress defects 150 in straight lines within the wafer. It is also possible for this embodiment that the laser be stationary and the chuck 134 move in the x-y plane.

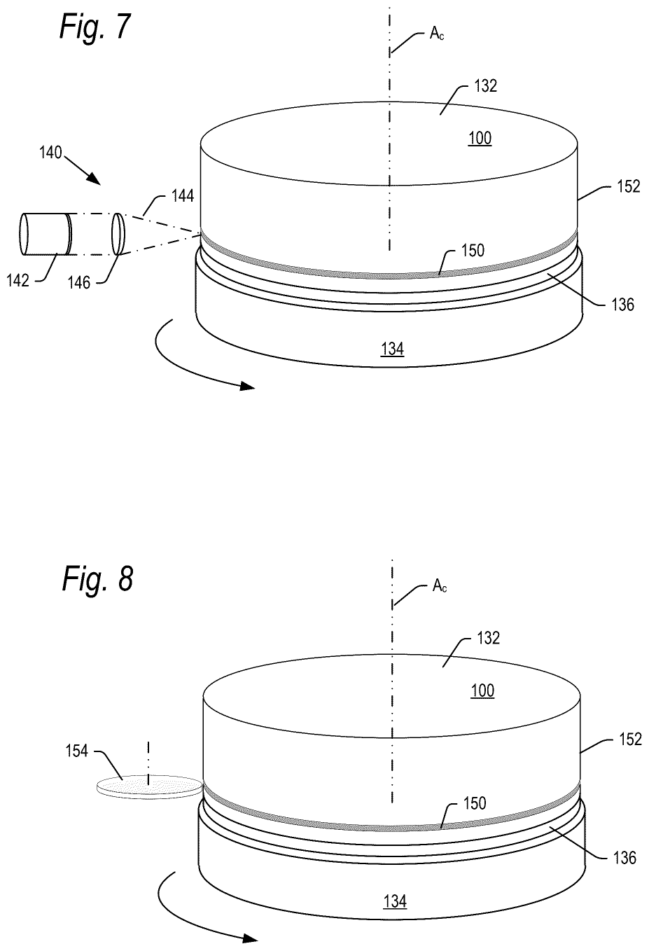

Given the low surface energy state of silicon in the {111} crystalline plane, it is not necessary that stress defects be created throughout a plane within the wafer. FIGS. 7 and 8 show further embodiments where stress defects are formed simply around an outer circumference of wafer 100. FIG. 7 shows an embodiment which may use the same set-up as FIG. 6. However, in this embodiment, instead of focusing the beam within the wafer, the laser assembly 140 generates discrete points of stress defects, or scores a line of stress defects 150, around the outer circumference 152 of wafer 100 as the wafer 100 rotates on chuck 134. FIG. 8 illustrates a further embodiment which uses a rotating saw blade 154 to score a line of stress defects 150 around the outer circumference 152 of wafer 100 as the wafer 100 rotates on chuck 134. In the embodiments of FIGS. 7 and 8, the laser/saw blade may score the outer circumference 152 to a depth of 5 μm to 1 mm, though the depth of the score may be lesser or greater than that in further embodiments.

In each of the embodiments of FIGS. 5-8, the stress defects (as discrete points or continuous lines) generate cracks in the wafer that readily propagate given the low surface energy of the {111} crystalline plane. The cracks through the wafer in the plane of the stress defects may propagate along a line between two or more adjacent stress defects 150. The cracks through the wafer in the plane of the stress defects may additionally or alternatively propagate in a plane between three or more adjacent stress defects 150. As long as there are one or more stress defects in the wafer at a given {111} crystalline plane, the low surface energy of that plane orientation may result in cracks that propagate in the plane until the wafer cleaves in two at the plane. This may happen with or without external load or agitation.

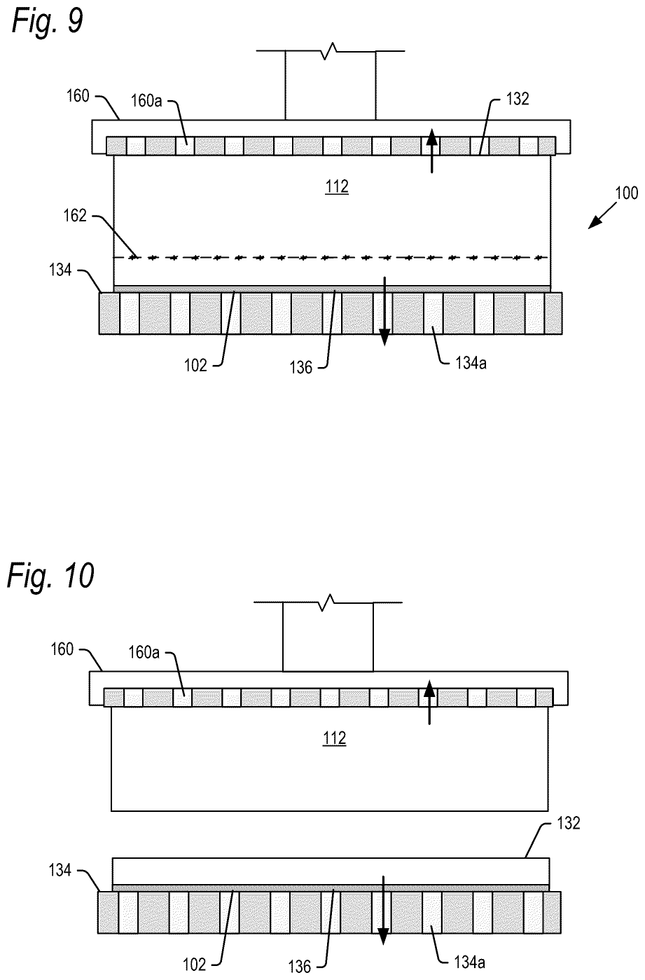

FIG. 9 is an edge view of wafer 100 supported on chuck 134. As noted, chuck 134 may be a vacuum chuck including ports 134a connected to a vacuum source to create a negative pressure holding the layer of tape 136 and active surface 102 against the vacuum chuck. After crack forming and propagation steps 216 and 218, a vacuum tip 160 may be positioned against the back surface 132 of wafer 100. Vacuum tip 160 may include ports 160a connected to a vacuum source to create a negative pressure holding the back surface 132 of wafer against the vacuum tip.

As explained above, the wafer 100 has been cleaved in two at at a plane of the stress defects, referred here as the cleave plane 162. In step 220, the vacuum tip may remove the severed portion of the wafer substrate 112 above the cleave plane 162, which may be discarded. The wafer 100 below the cleave plane 162 remaining on the vacuum chuck 134 includes the active surface 102 of integrated circuit dies 106, which is now at its final thickness. In one example, before the wafer cleaving of the present technology, the wafer may have a total thickness of 760 μm. In one example, the final thickness of the wafer 100 shown in FIG. 10 may be between 20 μm to 100 μm, including for example 25 μm and 36 μm.

As noted, the wafer may be completely cleaved after crack propagation from the stress defects 150. However, in the event the wafer is not completely cleaved, the pulling apart of the wafer by vacuum chuck 134 and vacuum tip 160 completes crack propagation and cleaving of the wafer 100.

After removal of the discarded portion of the wafer substrate 112 on vacuum tip 160, what remains on chuck 134 is the semiconductor wafer, thinned to the final desired thickness, with a highly planar back surface (again referred to as the back surface, or second major surface, 132) devoid of cracks or scratches. A layer of die attach film (DAF) adhered to a flexible dicing tape may be applied onto the second major surface 132 of the wafer 100 in step 224. The wafer 100 may then be turned over and supported on a vacuum chuck or other support surface, and the lamination tape on the active, first major surface 102 of the wafer 100 may be removed in step 226.

Thereafter, the wafer 100 may be diced in step 228. Dicing of the wafer may be performed for example using a known cutting blade. It is also known to dice wafers using a vertical stealth dicing process in which a laser forms layers of impact points in vertical planes (orthogonal to surfaces 102, 132) around the outline of each semiconductor die 106 in wafer 100. Thereafter, stresses on the wafer are generated which propagate the impact points along vertical crystalline planes to sever the individual semiconductor dies. Other dicing methods may be used.

After dicing step 228, the flexible dicing tape may be stretched along orthogonal axes to separate the individual semiconductor dies 106 in step 230. Thereafter, in step 232, individual semiconductor dies 106 may be removed by a pick and place robot for inclusion in a semiconductor package.

Crack propagation using horizonal stealth lasing or other methods described above to thin the wafer 100 provides several advantages. As noted in the Background, conventional backgrinding processes may generate cracks in semiconductor wafers, especially those that are currently made at thin, fragile thicknesses. Cleaving along the {111} crystalline plane according to the present technology eliminates wafer cracking due to the backgrinding processes. Elimination of such cracks improves wafer and die yields, and does away with the need for additional screening/inspection steps. Additionally, conventional backgrinding processes generate debris and foreign materials that can cause cracks and otherwise impair the assembly process. Elimination of the backgrinding process prevents the generation of this debris and foreign material, thus further improving yield and die quality. Moreover, the multiple backgrinding wheels needed for conventional wafer thinning add significant time, expense and complexity to the packaging process. Omission of the backgrinding wheels in accordance with the present technology improves each of these packaging parameters.

Additionally, crack propagation using the {111} crystalline plane provides higher yields as compared to wafer prepared with other crystal orientations. As noted, given the low surface energy of the {111} crystalline plane, the wafer is most easily cleaved along the {111} plane, so that, as cracks propagate, the cleaving will not deviate from the {111} plane. This has two benefits. First, this results in a highly planar, high quality back surface of the wafer in the {111} plane. Second, any attempt to cleave wafers formed with other crystalline plane orientations will result in crack propagation which moves into other crystalline planes. For example, if the method of the present technology were attempted using a wafer with a {001} plane orientation, the crack may deviate and move to the {110} plane or {111} plane with a lower required dissociation ability, thereby reducing the yield. Furthermore, as noted above, given the low surface energy of the silicon wafer in the {111} plane, it is only necessary to introduce a small number of stress defects, thereby providing a simpler fabrication process and increasing WPH as compared to other wafer thinning methods.

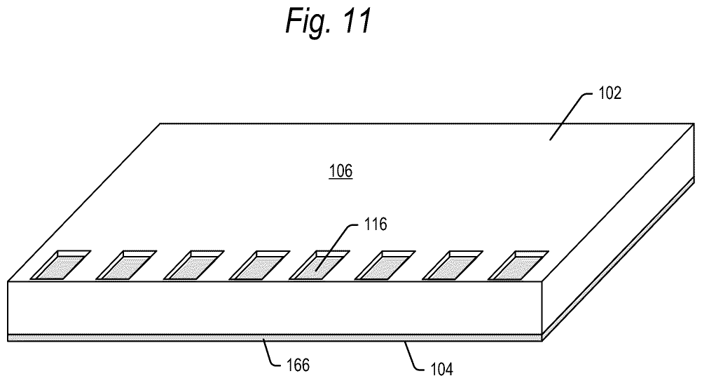

FIG. 11 shows an exemplary semiconductor die 106 after separation from wafer 100. The die 106 includes die bond pads 116 at the first major surface 102 of the die 106. The die 106 includes a lased, second major surface formed by the cleaving process described above. A DAF layer 166 is also shown on the second major surface 132.

In summary, an example of the present technology relates to a method of processing a semiconductor wafer comprising semiconductor dies, the semiconductor wafer having an active surface and a {111} crystalline plane orientation parallel to the active surface, the method comprising: forming one or more stress defects at a depth of the wafer corresponding to a final thickness of the wafer; and cleaving the wafer in a {111} plane of the one or more stress defects by crack propagation from the one or more stress defects.

In another example, the present technology relates to a method of processing a semiconductor wafer comprising semiconductor dies, the semiconductor wafer having an active surface the method comprising: forming a plurality of stress points in a plane having a {111} crystalline orientation at a depth of the wafer corresponding to a final thickness of the wafer; and cleaving the wafer in the {111} plane of the plurality of stress defects by crack propagation between the plurality of stress defects.

In a further example, the present technology relates to a method of fabricating flash memory semiconductor dies from a semiconductor wafer, the method comprising: receiving the semiconductor wafer, the semiconductor wafer having flash memory integrated circuits formed in an active surface of the semiconductor wafer and the semiconductor wafer thinned by the steps of: forming a plurality of stress points in a plane having a {111} crystalline orientation at a depth of the wafer corresponding to a final thickness of the wafer; and cleaving the wafer in the {111} plane of the plurality of stress defects by crack propagation between the plurality of stress defects; and dicing the flash memory semiconductor dies from the semiconductor wafer.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of processing a semiconductor wafer comprising semiconductor dies, the semiconductor wafer having an active surface and a {111} crystalline plane orientation parallel to the active surface, the method comprising:
forming one or more stress defects at a depth of the wafer corresponding to a final thickness of the wafer; and
cleaving the wafer in a {111} plane of the one or more stress defects by crack propagation from the one or more stress defects.

2. The method of claim 1, wherein the step of forming one or more stress defects comprises the step of forming the one or more stress defects by a laser forming the stress defects within an interior of the wafer by stealth lasing.

3. The method of claim 2, wherein the step of forming one or more stress defects by a laser forming the stress defects within an interior of the wafer by stealth lasing comprises the step of penetrating the wafer with a laser through a major planar surface of the wafer.

4. The method of claim 2, wherein the step of forming one or more stress defects by a laser forming the stress defects within an interior of the wafer by stealth lasing comprises the step of penetrating the wafer with a laser through an outer circumference of the of the wafer.

5. The method of claim 1, wherein the step of forming one or more stress defects comprises the step of forming the one or more stress defects by a laser forming the stress defects around an outer circumference of the wafer.

6. The method of claim 1, wherein the step of forming one or more stress defects comprises the step of forming the one or more stress defects by a saw blade forming the stress defects around an outer circumference of the wafer.

7. The method of claim 1, wherein the step of forming one or more stress defects comprises the step of forming a plurality of stress defects in the {111} plane.

8. The method of claim 1, wherein the step of forming one or more stress defects comprises the step of forming the stress defects at one or more discrete points.

9. The method of claim 1, wherein the step of forming one or more stress defects comprises the step of forming the stress defects at a plurality of discrete points.

10. The method of claim 1, wherein the step of forming one or more stress defects comprises the step of forming the stress defects in a continuous line.

11. The method of claim 1, wherein the step of forming one or more stress defects comprises the step of forming the stress defects in a curved pattern.

12. The method of claim 1, wherein the step of forming one or more stress defects comprises the step of forming the stress defects in a straight line.

13. The method of claim 1, wherein the cleaving the wafer in a {111} plane comprises the step of separating the semiconductor wafer so that the portion of the wafer including the active surface has a thickness of between 25 microns and 36 microns.

14. The method of claim 1, further comprising the step of forming flash memory integrated circuits in the active surface of the wafer.

15. A method of processing a semiconductor wafer comprising semiconductor dies, the semiconductor wafer having an active surface the method comprising:
forming a plurality of stress points in a plane having a {111} crystalline orientation at a depth of the wafer corresponding to a final thickness of the wafer; and
cleaving the wafer in the {111} plane of the plurality of stress defects by crack propagation between the plurality of stress defects.

16. The method of claim 15, further comprising the step of engaging a major planar surface of the wafer, opposite the active surface of the wafer, with a vacuum tip to remove a portion of the wafer after said step of cleaving the wafer.

17. The method of claim 15, wherein the step of forming one or more stress defects comprises the step of forming the one or more stress defects by a laser forming the stress defects within an interior of the wafer by stealth lasing.

18. The method of claim 15, wherein the step of forming one or more stress defects comprises the step of forming the one or more stress defects by a laser forming the stress defects around an outer circumference of the wafer.

19. The method of claim 15, wherein the step of forming one or more stress defects comprises the step of forming the one or more stress defects by a saw blade forming the stress defects around an outer circumference of the wafer.

20. A method of fabricating flash memory semiconductor dies from a semiconductor wafer, the method comprising:
receiving the semiconductor wafer, the semiconductor wafer having flash memory integrated circuits formed in an active surface of the semiconductor wafer and the semiconductor wafer thinned by the steps of:
forming a plurality of stress points in a plane having a {111} crystalline orientation at a depth of the wafer corresponding to a final thickness of the wafer; and
cleaving the wafer in the {111} plane of the plurality of stress defects by crack propagation between the plurality of stress defects; and
dicing the flash memory semiconductor dies from the semiconductor wafer.
